(19) United States
(12) Patent Application Publication
(10) Pub. No.: US 2023/0176420 A1
(43) Pub. Date: Jun. 8, 2023

(54) LIGHT GUIDE PLATE, PLANAR LIGHT SOURCE APPARATUS, DISPLAY APPARATUS, AND ELECTRONIC DEVICE

(71) Applicant: NICHIA CORPORATION, Anan-shi (JP)

(72) Inventors: Shotaro WATANABE, Tsurugashima-shi (JP); Naoki ISHIMI, Tokyo (JP); Yoshinori ITO, Kyoto-shi (JP); Tomokazu SHIMODA, Tsurugashima-shi (JP)

(73) Assignee: NICHIA CORPORATION, Anan-shi (JP)

(21) Appl. No.: 18/162,392

(22) Filed: Jan. 31, 2023

Related U.S. Application Data
(62) Division of application No. 16/339,734, filed on Apr. 5, 2019.

(30) Foreign Application Priority Data
Dec. 22, 2016 (JP) 2016-249344

(51) Int. Cl. G02F 1/13357; G02F 1/1335; F21V 8/00

(52) U.S. Cl. CPC G02F 1/133606; G02F 1/133603; G02F 1/133524; G02B 6/0028; G02F 1/133611; G02B 6/0021; G02B 6/0016; G02B 6/0036; G02B 6/0051; G02B 6/0018; G02B 6/0025; G02B 6/003; G02B 6/0053; G02F 1/133605; G02F 2201/305; G02B 6/0055; G02B 6/0031; G02B 6/0073; G02F 1/133607

(57) ABSTRACT

An object is to promote a reduction in thickness of a light guide plate and to provide a technique for suppressing brightness non-uniformity in the light guide plate. A light guide plate includes: a depressed portion provided on an opposite side of a light exit surface from which light is emitted; a first direction changing portion which is provided inside the depressed portion and above a light emitting element in a direction oriented toward the light exit surface, the light emitting element being provided on the opposite side of the light exit surface, and which changes a direction of travel of at least a part of light of the light emitting element; and a second direction changing portion which is provided above the light emitting element and higher than the light exit surface and which changes a direction of travel of at least a part of light of the light emitting element.

### TECHNICAL FIELD

The present invention relates to a light guide plate, a planar light source apparatus, a display apparatus, and an electronic device.

### BACKGROUND ART

Backlight systems for liquid crystal display apparatuses include a system referred to as an edge light-type backlight and a system referred to as a direct-type backlight. Direct-type backlights which feature high light utilization efficiency and which enable higher brightness to be readily achieved are used in displays of large-size liquid crystal display apparatuses. In addition, for example, an LED (Light Emitting Diode) which emits white light is used as a light source of a backlight. In the case of a direct-type backlight, while a plurality of LEDs are arranged directly underneath a liquid crystal display apparatus, brightness non-uniformity easily occurs on the liquid crystal display apparatus between portions directly above the LEDs and other portions.

Conventionally, a planar light source apparatus has been proposed in which a light source is installed in a conical depression for light source insertion provided on a rear surface of a light guide plate, and light-scattering dots for scattering light inside the light guide plate are provided on the rear surface of the light guide plate, the planar light source apparatus being configured so that at least a part of light from the light source is first reflected by a front surface and/or the rear surface of the light guide plate and subsequently emitted from the front surface of the light guide plate (refer to Patent Document 1).

### CITATION LIST

[Patent Document]

[Patent Document 1] Japanese Patent No. 3427636

### SUMMARY OF INVENTION

### Technical Problem

In addition, it is conventionally difficult to simultaneously achieve a reduction in thickness and suppression of brightness non-uniformity of a light guide plate. In consideration of such circumstances, an object of the present invention is to promote a reduction in thickness of a light guide plate and to provide a technique for suppressing brightness non-uniformity in the light guide plate.

### Solution to Problem

A light guide plate according to the present invention includes: a depressed portion provided on an opposite side of a light exit surface from which light is emitted; a first direction changing portion which is provided inside the depressed portion and above a light emitting element in a direction oriented toward the light exit surface, the light emitting element being provided on the opposite side of the light exit surface, and which changes a direction of travel of at least a part of light of the light emitting element; and a second direction changing portion which is provided above the light emitting element and higher than the light exit surface and which changes a direction of travel of at least a part of light of the light emitting element.

By adopting such a configuration, even when a thickness of the light guide plate cannot be increased, an irradiated region of light from the light emitting element can be widened and, at the same time, the light can be dispersed so that light distribution does not concentrate directly above the light emitting element. In other words, a reduction in thickness of a light guide plate can be promoted and brightness non-uniformity of the light guide plate can be suppressed.

In addition, each of the first direction changing portion and the second direction changing portion may be formed from a material that shields, reflects, or diffuses light. According to such a configuration, brightness non-uniformity can be suppressed.

The light guide plate may further include an optical film laminated on the light exit surface, and the second direction changing portion may be provided on the optical film. Specifically, the second direction changing portion may be provided on the optical film that is a diffusing sheet, a prism sheet, or the like included in a general planar light source apparatus.

In addition, the first direction changing portion may be a first diffraction grating formed inside the depressed portion of the light guide plate, and the second direction changing portion may be a second diffraction grating formed on the light exit surface. For example, brightness non-uniformity can be suppressed even according to such a configuration.

Furthermore, a light guide plate according to the present invention includes a first depressed portion that is provided on an opposite side of a light exit surface from which light is emitted and that houses a light emitting element, wherein the first depressed portion may have a conical shape, a truncated cone shape, a pyramid shape, or a truncated pyramid shape, and a second depressed portion having a conical shape, a truncated cone shape, a pyramid shape, a truncated pyramid shape, or a bowl shape may be provided on a side of the light exit surface of the light guide plate and above the first depressed portion in a direction oriented toward the light exit surface.

By adopting such a configuration, even when a thickness of the light guide plate cannot be increased, light from the light emitting element can be refracted, reflected, or the like by a side surface of the first depressed portion and a side surface of the second depressed portion and an irradiated region due to light from the light exit surface can be widened. In other words, a reduction in thickness of a light guide plate can be promoted and brightness non-uniformity of the light guide plate can be suppressed.

In addition, each of the first depressed portion and the second depressed portion may include a Fresnel lens that diffuses light of the light emitting element. Accordingly, the irradiated region due to light from the light exit surface can be widened and brightness non-uniformity can be suppressed without increasing the thickness of the light guide plate.

Furthermore, the present invention may be provided as a planar light source apparatus including the light guide plate described above and a light emitting element housed inside a depressed portion or as a display apparatus including such a planar light source apparatus and a display panel which receives light emitted from the planar light source apparatus. In addition, the planar light source apparatus may further include a transparent resin layer arranged between the light guide plate and the light emitting element.

Furthermore, the present invention may be provided as an electronic device including the display apparatus.

### Advantageous Effects of Invention

According to the present invention, a reduction in thickness of a light guide plate can be promoted and a technique for suppressing brightness non-uniformity of a liquid crystal display apparatus can be provided.

### BRIEF DESCRIPTION OF DRAWINGS

FIG. 1 is a perspective view illustrating a configuration of a liquid crystal display apparatus.

FIG. 2 is a perspective view illustrating a configuration of a planar light source apparatus.

FIG. 3A is a sectional view schematically showing a light guide plate according to a first embodiment.

FIG. 3B is a sectional view schematically showing the light guide plate according to the first embodiment.

FIG. 4 is a sectional view schematically showing a light guide plate according to a second embodiment.

FIG. 5 is a sectional view schematically showing a light guide plate according to a third embodiment.

FIG. 6 is a sectional view schematically showing a light guide plate according to a fourth embodiment.

FIG. 7 is a sectional view schematically showing a light guide plate according to a fifth embodiment.

FIG. 8 is a sectional view schematically showing a light guide plate according to a sixth embodiment.

FIG. 9 is a sectional view schematically showing a light guide plate according to a seventh embodiment.

FIG. 10 is a sectional view schematically showing a light guide plate according to an eighth embodiment.

FIG. 11 is a sectional view schematically showing a light guide plate according to a ninth embodiment.

FIG. 12 is a sectional view schematically showing a light guide plate according to a tenth embodiment.

FIG. 13 is a sectional view schematically showing a light guide plate according to an eleventh embodiment.

FIG. 14 is a sectional view schematically showing a light guide plate according to a twelfth embodiment.

### DESCRIPTION OF EMBODIMENTS

Hereinafter, embodiments of the present invention will be described with reference to the drawings. It is to be understood that the embodiments described below merely represent examples of implementing the present invention and are not intended to limit the present invention to the specific configurations described hereinafter.

In the embodiments described below, the “display apparatus” will be described as a liquid crystal display apparatus and the “planar light source apparatus” will be described as a backlight of the liquid crystal display apparatus.

### (Configuration of Liquid Crystal Display Apparatus)

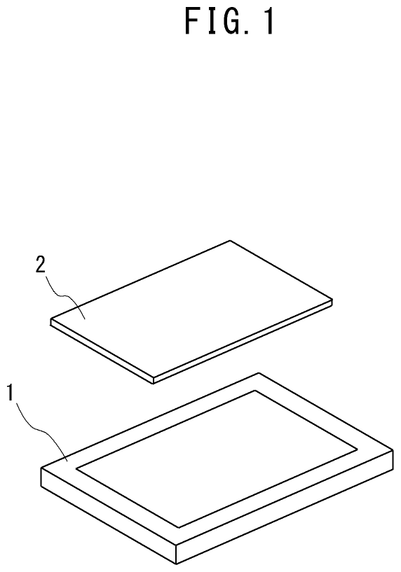

FIG. 1 is a perspective view illustrating a configuration of a liquid crystal display apparatus. As shown in FIG. 1, the liquid crystal display apparatus includes: a planar light source apparatus 1 arranged as a backlight; and a display panel 2 which receives light emitted from the planar light source apparatus 1. The display panel 2 displays images by applying voltage to liquid crystals encapsulated by being sandwiched between glass plates and increasing or reducing transmittance of light. Hereinafter, in the planar light source apparatus 1, a side of the display panel 2 may be described as an upper surface side and a side of an opposite surface thereof may be described as a lower surface side. In other words, a side of a light exit surface of the planar light source apparatus 1 will be referred to as up.

### (Configuration of Planar Light Source Apparatus)

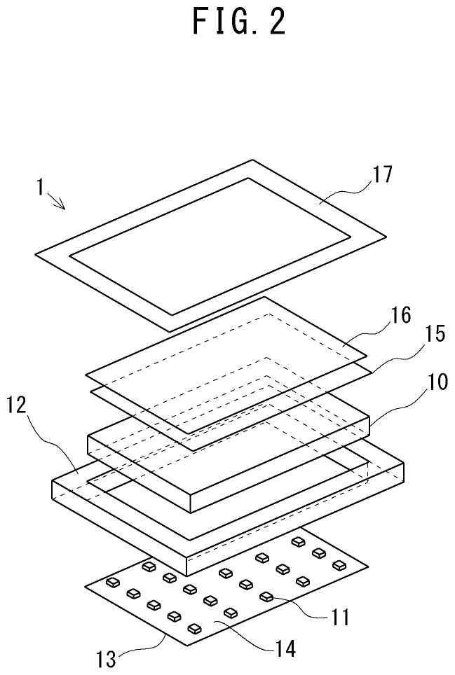

FIG. 2 is a perspective view illustrating a configuration of the planar light source apparatus 1. The planar light source apparatus 1 includes a light guide plate 10 and a frame 12. In addition, the planar light source apparatus 1 includes a plurality of light sources 11, a mounting substrate 13, and a reflective layer 14 arranged on the lower surface side of the light guide plate 10. The lower surface side of the light guide plate 10 refers to an opposite side of a side on which the display panel 2 is arranged. The planar light source apparatus 1 further includes a diffusing sheet 15, a prism sheet 16, and a light shielding member 17 laminated in order on the upper surface side of the light guide plate 10. The upper surface side of the light guide plate 10 is the side on which the display panel 2 is arranged. One or a plurality of prism sheets 16 may be provided.

The light guide plate 10 has an approximately flat plate shape and is molded from a translucent material such as a polycarbonate resin or a polymethyl methacrylate (acrylic) resin. An upper surface of the light guide plate 10 is a light exit surface from which light is emitted and which faces the display panel 2. The light guide plate 10 is configured such that light incident into the light guide plate 10 is guided to the light exit surface and the entire light exit surface is uniformly lighted.

The light source 11 emits white light from a light-emitting surface. While the light source 11 is, for example, an LED package, a light source other than an LED package may be used instead. The light source 11 is formed by encapsulating an LED chip that is a light emitting element (a light emitting portion) with a translucent resin (resin layer) containing phosphor. Instead of arranging the phosphor on the LED chip, a phosphor layer may be arranged on the light exit surface of the light guide plate 10 or a phosphor layer may be arranged on the diffusing sheet 15. The light source 11 is driven by receiving supply of power from the mounting substrate 13. An LED light source with a color other than white may be used as the light source 11. The light source 11 is arranged below the light guide plate 10.

The frame 12 is a frame-like member (also referred to as a “frame body”) which has an opening and which is constituted by four sides. The frame 12 is molded from a polycarbonate resin containing titanium oxide, a polycarbonate resin not containing titanium oxide, or the like. The light guide plate 10 is fitted into the frame 12, and an inner circumferential surface of the frame 12 surrounds a side surface of the light guide plate 10 that forms an outer circumferential surface of the light guide plate 10. The frame 12 has high reflectance and reflects and reuses light having leaked from the side surface of the light guide plate 10. The mounting substrate 13 is a wiring substrate on which wiring is provided by a conductive foil on an insulating substrate.

The plurality of light sources 11 and the reflective layer 14 are provided on the mounting substrate 13. The reflective layer 14 is provided around the light sources 11. The reflective layer 14 is, for example, a white resin, a metal foil, or the like with high reflectance and reflects light so that light inside the light guide plate 10 does not leak from the lower surface of the planar light source apparatus 1. The diffusing sheet 15 is a semi-transparent resin film which diffuses light emitted from the light exit surface of the light guide plate 10 and which widens directional characteristics of the light. The prism sheet 16 is a transparent resin film which has a fine triangular prism-shaped pattern formed on an upper surface thereof and which collects light diffused by the diffusing sheet 15 and increases brightness when the planar light source apparatus 1 is viewed from the upper surface side.

The light shielding member 17 has a frame shape when the planar light source apparatus 1 is viewed from the upper surface side. The frame shape need only be a closed-loop shape and may be, for example, a rectangle shape, an approximately ellipsoidal shape, or another shape. For example, the light shielding member 17 may be a black adhesive tape in which both upper and lower faces are adhesive faces. A frame portion of the light shielding member 17 is bonded along an upper end of the frame 12 and prevents light from leaking out from the planar light source apparatus 1.

### First Embodiment

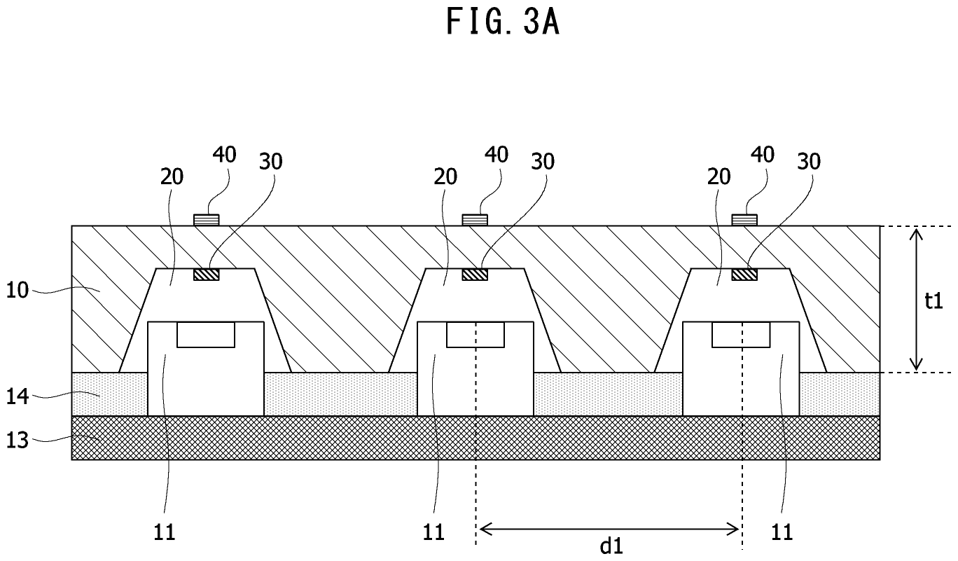

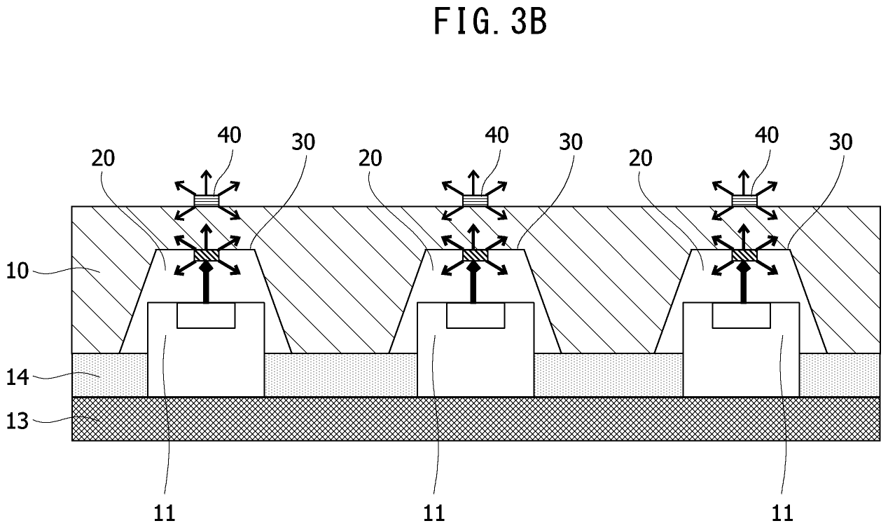

FIG. 3A is a sectional view schematically showing the light guide plate 10. The light guide plate 10 has a plurality of depressed portions 20 on the lower surface of the light guide plate 10. In other words, the depressed portions 20 are opened downward and depressed upward relative to the light guide plate 10. In addition, the plurality of light sources 11 are arranged on the mounting substrate 13, with one light source 11 being housed inside each depressed portion 20. The depressed portions 20 are also referred to as housing portions. In addition, light emitted from the light sources 11 is incident into the light guide plate 10. Due to light incident into the light guide plate 10 being refracted, reflected, and diffused inside the light guide plate 10 and emitted from a light exit surface of the light guide plate 10, the light exit surface of the light guide plate 10 is uniformly lighted. A thickness (height) t1 of the light guide plate 10 and a pitch between the light sources 11 are arbitrary values. Furthermore, optical films including the diffusing sheet 15 and the prism sheet 16 are laminated on the light exit surface that is the upper surface side of the light guide plate 10. A ratio of sizes of the respective components and the like are not limited to the illustrated example.

The depressed portion 20 has a truncated cone shape and a diameter of the depressed portion 20 decreases from the opening (downward) of the depressed portion 20 toward the back (upper end) of the depressed portion 20. A diameter of a bottom surface (upper end) of the depressed portion 20 and a height (depth) of the depressed portion 20 are arbitrary values and a shape and a size of the depressed portion 20 are not particularly limited. For example, instead of a truncated cone, the depressed portion 20 may have a bell shape in which a back end of the depressed portion 20 is made into a curved surface or the depressed portion 20 may have a conical shape. A shape, a height, and a width of the light source 11 are also not particularly limited and the light source 11 need only have a shape and a size which enable the light source 11 to be housed inside the depressed portion 20.

In addition, the planar light source apparatus 1 according to the present embodiment respectively includes, in the depressed portion 20 and on the light exit surface, direction changing portions which change a direction of travel of light emitted from the light source 11. Specifically, a first direction changing portion 30 is provided in a back end portion of the depressed portion 20 near a position on a line which passes through the light source 11 and which is perpendicular to the light exit surface. In addition, a second direction changing portion 40 is provided on the light exit surface near a foot of a perpendicular dropped from the light source 11 to the light exit surface. The first direction changing portion 30 and the second direction changing portion 40 are each formed from a material that shields, reflects, or diffuses light. Alternatively, the first direction changing portion 30 and the second direction changing portion 40 may be formed by applying a coat of ink with prescribed characteristics such as shielding, reflecting, or diffusing light.

FIG. 3B is a diagram for illustrating a path of light according to the present embodiment. For example, with the light source 11, light intensity is highest in a direction directly above the light source 11. As indicated by thick solid arrows in FIG. 3B, light emitted in a directly upward direction from the light source 11 is made incident to the first direction changing portion 30 and is shielded, reflected, or diffused. In addition, light having passed the first direction changing portion 30 is further made incident to the second direction changing portion 40 and is shielded, reflected, or diffused.

In particular, when a distance from the light source 11 to the display panel 2 that is an irradiating surface of light is short, it is difficult to make luminance on the display panel 2 uniform and luminance tends to be higher the closer to a position directly above the light source 11. According to the first direction changing portion 30 and the second direction changing portion 40 shown in FIG. 3A, straight light emitted directly upward from the light source 11 can be shielded, reflected, or diffused and an occurrence of brightness non-uniformity can be suppressed. Alternatively, the direction changing portion 30 and the direction changing portion 40 may be provided in a portion corresponding to a peak of light intensity of light emitted from the light source 11.

### Second Embodiment

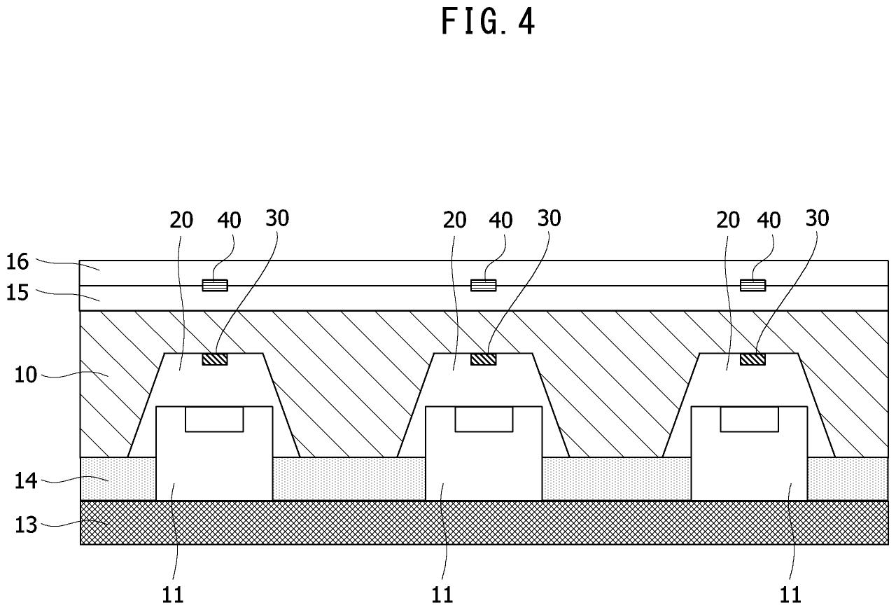

FIG. 4 is a sectional view schematically showing the light guide plate 10 according to a second embodiment. A ratio of sizes of the respective components and the like are not limited to the illustrated example. In the present embodiment, components corresponding to the configuration described above will be assigned corresponding reference numerals and a description thereof will be omitted.

The light guide plate 10 according to the present embodiment also includes two direction changing portions. Specifically, the first direction changing portion 30 is provided in a back end portion of the depressed portion 20 near a position on a line which passes through the light source 11 and which is perpendicular to the light exit surface. In addition, the second direction changing portion 40 is provided between the diffusing sheet 15 and the prism sheet 16 near a foot of a perpendicular dropped from the light source 11 to the diffusing sheet 15 or the prism sheet 16. To sum up the first embodiment and the second embodiment, the first direction changing portion 30 and the second direction changing portion 40 are provided directly above the light source 11. In other words, the first and second embodiments are provided with the first direction changing portion 30 and the second direction changing portion 40 which change, in two stages, a direction of travel of at least a part of light from the light source 11. In addition, the first direction changing portion 30 and the second direction changing portion 40 are each formed from a material that shields, reflects, or diffuses light. The first direction changing portion 30 and the second direction changing portion 40 according to the present embodiment may also be formed by applying a coat of ink with prescribed characteristics.

Even according to the first direction changing portion 30 and the second direction changing portion 40 shown in FIG. 4, straight light emitted directly upward from the light source 11 can be shielded, reflected, or diffused and an occurrence of brightness non-uniformity can be suppressed. The first direction changing portion 30 and the second direction changing portion 40 may be provided at positions other than those shown in FIG. 4 as long as the positions are directly above the light source 11. For example, the second direction changing portion 40 may be provided on the prism sheet 16.

### Third Embodiment

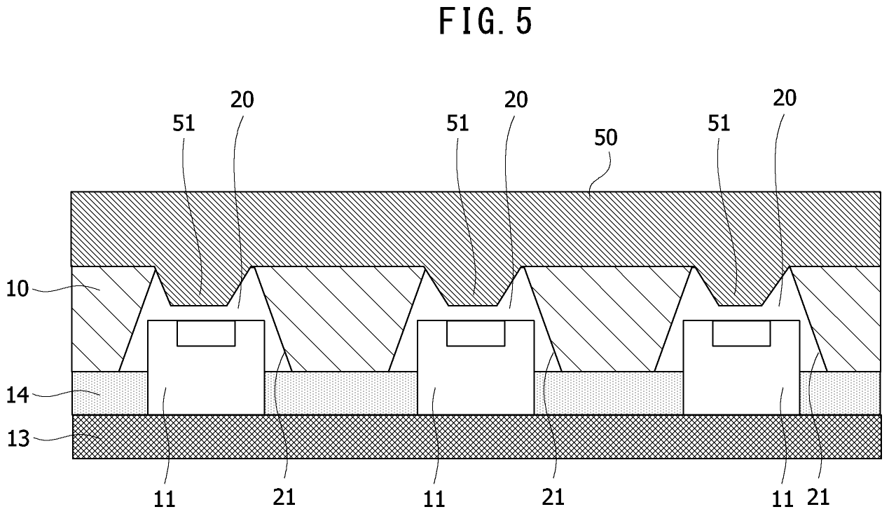

FIG. 5 is a sectional view schematically showing the light guide plate 10 according to a third embodiment. A ratio of sizes of the respective components and the like are not limited to the illustrated example. In the present embodiment, components corresponding to the configurations described above will be assigned corresponding reference numerals and a description thereof will be omitted.

The depressed portion 20 shown in FIG. 5 is a depression with a truncated cone shape provided on the light guide plate 10 and is configured as a through-hole. In addition, the diameter of the depressed portion 20 decreases from an opening on the lower surface side toward an opening on the upper surface side. In other words, a housing portion of the light source 11 according to the present embodiment is configured as a through-hole with a tapered side surface.

In addition, a light diffusing layer 50 formed by a diffusing material that diffuses light is provided on a side of the light exit surface (upper surface side) of the light guide plate 10. The diffusing material is, for example, a resin molded article having particles with random sizes and different refractive indexes dispersed therein, and diffuses light emitted from the light exit surface of the light guide plate 10 and widens directional characteristics of the light. Furthermore, the light diffusing layer 50 has a plurality of protruded portions 51 with truncated cone shapes, and each of the protruded portions 51 is inserted into the depressed portion 20 of the light guide plate 10. The diffusing sheet 15 and the prism sheet 16 (not illustrated) are laminated on an upper surface side of the light diffusing layer 50.

The planar light source apparatus shown in FIG. 5 combines, with the light guide plate 10, the light diffusing layer 50 which is formed of a member that differs from the light guide plate 10 formed of polycarbonate, acrylic, or the like. According to such a configuration, light from the light source 11 can be refracted in a diffusion direction by a side surface 21 of the depressed portion 20 and light incident to the light diffusing layer 50 can be further diffused. In addition, the protruded portion 51 of the light diffusing layer 50 is positioned approximately directly above the light source 11. By increasing thickness of a portion approximately directly above the light source 11 where brightness tends to be highest and refracting light with the side surface of the protruded portion 51 which has a truncated cone shape, an occurrence of brightness non-uniformity can be suppressed. In addition, when the light guide plate 10 and the light diffusing layer 50 shown in FIG. 5 are integrally molded instead of being divided into two parts, a mold with a shape similar to that of the depressed portion 20 is to be used. While the shape of the depressed portion 20 has a pointed upper end, such a shape is prone to damage and makes it difficult to maintain diffusion performance of an integrally molded component. Therefore, there is an advantage of forming the light guide plate 10 and the light diffusing layer 50 as two parts.

### Fourth Embodiment

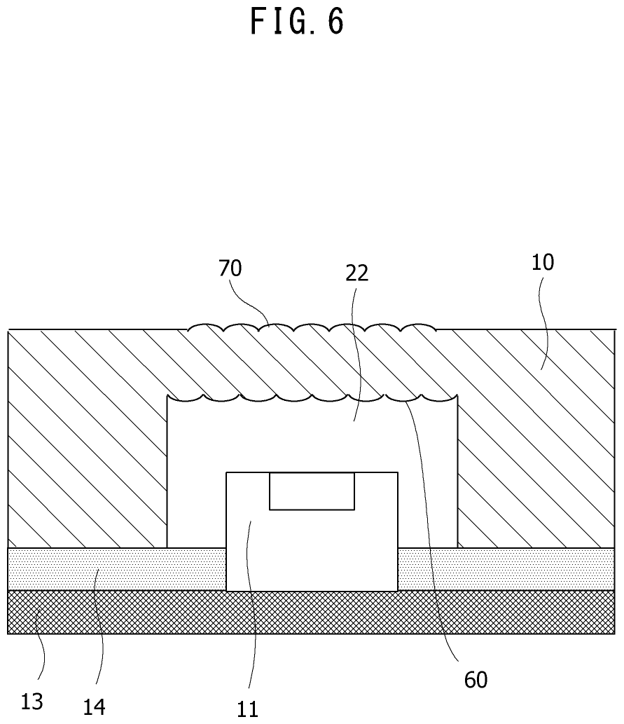

FIG. 6 is a sectional view schematically showing the light guide plate 10 according to a fourth embodiment. A ratio of sizes of the respective components and the like are not limited to the illustrated example. In addition, although only one depressed portion 22 is depicted in the example shown in FIG. 6, the light guide plate 10 is provided with a plurality of components including the depressed portion 22 at a prescribed pitch. In the present embodiment, components corresponding to the configurations described above will be assigned corresponding reference numerals and a description thereof will be omitted.

The planar light source apparatus shown in FIG. 6 includes the depressed portion 22 which is a columnar depression with one bottom surface thereof open and which constitutes a housing portion for housing the light source 11. A diameter of the bottom surface of the depressed portion 22 and a height (depth) of the depressed portion 22 are arbitrary values. For example, a shape other than a column such as a prism or a truncated cone may be adopted. In addition, a shape, a height, and a width of the light source 11 are also not particularly limited and the light source 11 need only have a shape and a size which enable the light source 11 to be housed inside the depressed portion 22.

The light guide plate 10 according to the present embodiment has a first diffraction grating 60 and a second diffraction grating 70 approximately directly above the light source 11. The first diffraction grating 60 is provided in a back end portion of the depressed portion 22. The second diffraction grating 70 is provided on a side of the light exit surface of the light guide plate 10. In addition, the first diffraction grating 60 and the second diffraction grating 70 are concentrically provided in a plan view from above the side of the light exit surface. The first diffraction grating 60 and the second diffraction grating 70 may have a same shape. In the present embodiment, the first diffraction grating 60 and the second diffraction grating 70 are respectively provided so as to have a prescribed diffraction angle and to widen an irradiated region of light from the light source 11. In other words, by providing diffraction gratings at an appropriate pitch, a direction in which light from the light source 11 is diffracted is controlled and the irradiated region on the display panel 2 is widened.

Even with the configuration described in the present embodiment, light from the light source 11 can be diffused and irradiated to the display panel 2. An occurrence of brightness non-uniformity can also be suppressed by adopting a configuration in which a direction of travel of light is changed in two stages as described above.

In the first to fourth embodiments, some kind of a direction changing portion which changes a direction of travel of at least a part of light from the light source 11 is provided at two positions, namely, a position inside the depressed portion that houses the light source 11 and a position above the light exit surface. Accordingly, even when a thickness of the light guide plate cannot be increased, an irradiated region of light from the light source 11 can be widened and, at the same time, the light can be dispersed so that light distribution does not concentrate directly above the light source 11. In other words, a reduction in thickness of a light guide plate can be promoted and brightness non-uniformity of a liquid crystal display apparatus can be suppressed.

### Fifth Embodiment

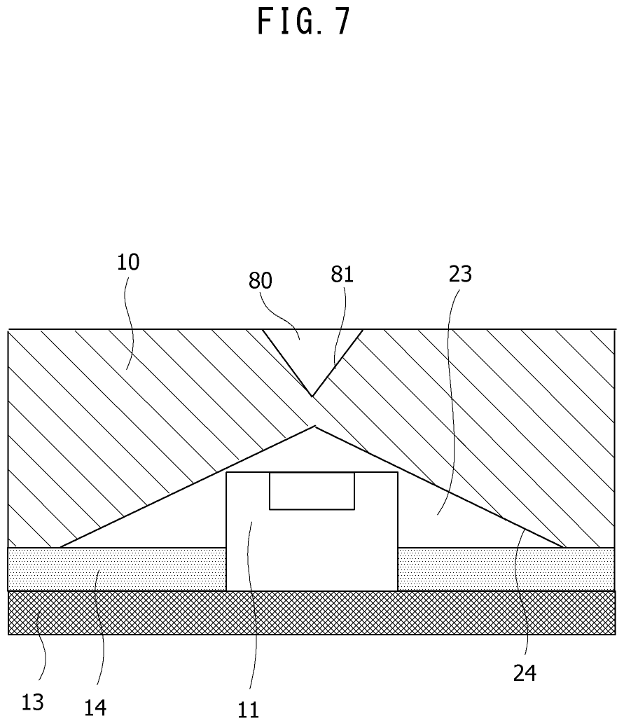

FIG. 7 is a sectional view schematically showing the light guide plate 10 according to a fifth embodiment. A ratio of sizes of the respective components and the like are not limited to the illustrated example. In addition, although only one depressed portion 23 is depicted in the example shown in FIG. 7, the light guide plate 10 is provided with a plurality of components including the depressed portion 23 at a prescribed pitch. In the present embodiment, components corresponding to the configurations described above will be assigned corresponding reference numerals and a description thereof will be omitted.

The light guide plate 10 shown in FIG. 7 includes the depressed portion 23 which is a conical depression with an open bottom surface and which constitutes a housing portion for housing the light source 11. A diameter of the bottom surface of the depressed portion 23 and a height (depth) of the depressed portion 23 are arbitrary values. Alternatively, the depressed portion 23 may have a truncated cone shape, a pyramid shape, a truncated pyramid shape, or the like. In addition, a shape, a height, and a width of the light source 11 are also not particularly limited and the light source 11 need only have a shape and a size which enable the light source 11 to be housed inside the depressed portion 23.

Furthermore, a depressed portion 80 which is a conical depression is provided approximately directly above the light source 11 on a side of the light exit surface of the light guide plate 10. A diameter of a bottom surface of the depressed portion 80 and a height (depth) of the depressed portion 80 are also arbitrary values. Alternatively, the depressed portion 80 may have a truncated cone shape.

With the light guide plate 10 according to the present embodiment, a part of light from the light source 11 incident to and refracted by a side surface 24 of the depressed portion 23 can be made further incident to and refracted by a side surface 81 of the depressed portion 80 or reflected by the side surface 81. Even in the present embodiment, the depressed portion 23 and the depressed portion 80 are respectively provided so as to widen an irradiated region of light from the light source 11.

Even with the configuration described in the present embodiment, light from the light source 11 can be diffused and irradiated to the display panel 2. An occurrence of brightness non-uniformity can also be suppressed by adopting a configuration in which a direction of travel of light is changed in two stages as described above.

### Sixth Embodiment

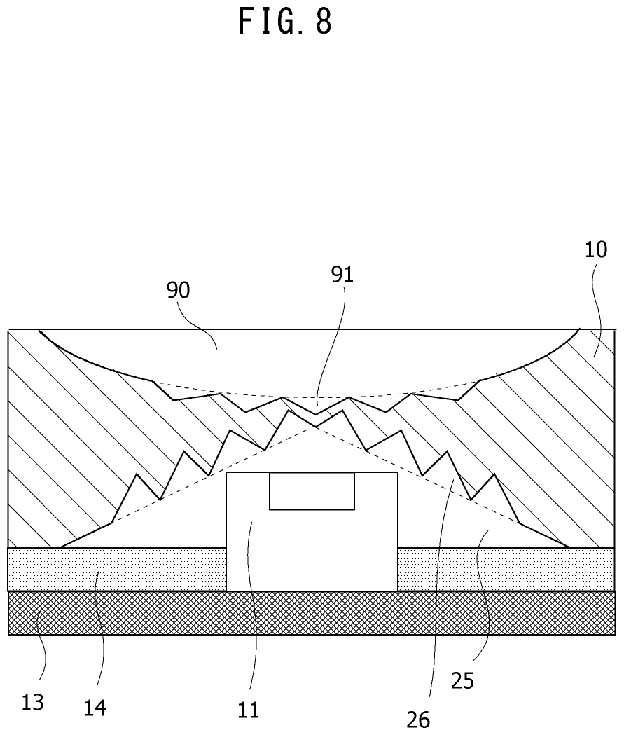

FIG. 8 is a sectional view schematically showing the light guide plate 10 according to a sixth embodiment. A ratio of sizes of the respective components and the like are not limited to the illustrated example. In addition, although only one depressed portion 25 is depicted in the example shown in FIG. 8, the light guide plate 10 is provided with a plurality of components including the depressed portion 25 at a prescribed pitch. In the present embodiment, components corresponding to the configurations described above will be assigned corresponding reference numerals and a description thereof will be omitted.

The planar light source apparatus shown in FIG. 8 includes the depressed portion 25 which is a conical depression with an open bottom surface and which constitutes a housing portion for housing the light source 11. A diameter of the bottom surface of the depressed portion 25 and a height (depth) of the depressed portion 25 are arbitrary values. Alternatively, the depressed portion 25 may have a truncated cone shape, a pyramid shape, a truncated pyramid shape, or the like. In addition, a shape, a height, and a width of the light source 11 are also not particularly limited and the light source 11 need only have a shape and a size which enable the light source 11 to be housed inside the depressed portion 25. Furthermore, irregularities 26 with a Fresnel lens shape are formed on a side surface of the depressed portion 25 according to the present embodiment. The irregularities 26 are formed so as to cover a portion approximately directly above the light source 11 and are configured to change a direction of travel of light emitted by the light source 11 so as to widen an irradiated region toward the display panel 2.

In addition, a depressed portion 90 which is a bowl-shape depression formed by a curved surface is provided on a side of the light exit surface of the light guide plate 10. Furthermore, irregularities 91 with a Fresnel lens shape are formed in a part of the surface of the depressed portion 90. The irregularities 91 are also formed so as to cover a portion approximately directly above the light source 11 and are configured to change a direction of travel of light emitted by the light source 11 so as to widen an irradiated region toward the display panel 2 (not illustrated). In other words, the irregularities 91 change a direction in which light from the light source 11 is diffracted to a steeper angle and widens the irradiated region on the display panel 2.

Even with the configuration described in the present embodiment, light from the light source 11 can be diffused and irradiated to the display panel 2. An occurrence of brightness non-uniformity can also be suppressed by adopting a configuration in which a direction of travel of light is changed in two stages as described above. In addition, a Fresnel lens may be provided on a plane parallel to the display panel 2 on at least one of the side of the light exit surface of the light guide plate 10 and the side of the light source 11. Accordingly, a thickness of the light guide plate 10 may be reduced.

### Seventh Embodiment

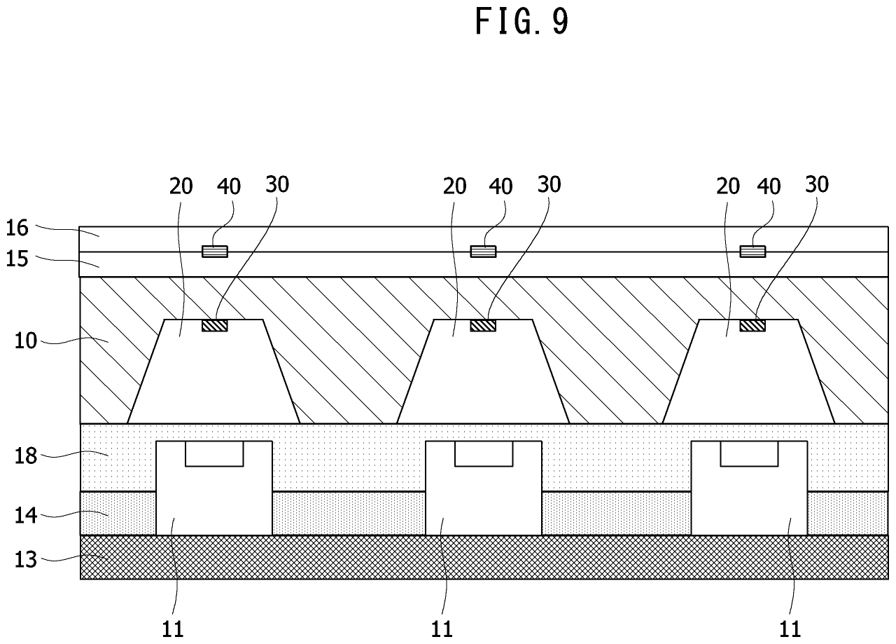

FIG. 9 is a sectional view schematically showing the light guide plate 10 according to a seventh embodiment. A ratio of sizes of the respective components and the like are not limited to the illustrated example. In the present embodiment, components corresponding to the configurations described above will be assigned corresponding reference numerals and a description thereof will be omitted.

For example, the light source 11 may be covered by a transparent resin layer 18. In an example shown in FIG. 9, the transparent resin layer 18 is arranged between the light guide plate 10 and the plurality of light sources 11 and the reflective layer 14. In other words, the plurality of light sources 11 are embedded in the transparent resin layer 18. In addition, the light guide plate 10 is arranged on top of the transparent resin layer 18 and the light sources 11 are not housed inside the depressed portions 20 of the light guide plate 10. Furthermore, the lower surface of the light guide plate 10 is in contact with the transparent resin layer 18 but the lower surface of the light guide plate 10 and the reflective layer 14 are not in contact with each other. An upper surface of the transparent resin layer 18 is a flat surface that is in contact with the light guide plate 10. Light emitted from the light sources 11 passes through the transparent resin layer 18 and is made incident to the light guide plate 10.

In the present embodiment, the first direction changing portion 30 and the second direction changing portion 40 are provided at positions similar to those in the second embodiment. Even according to such a configuration, straight light emitted directly upward from the light source 11 can be shielded, reflected, or diffused and an occurrence of brightness non-uniformity can be suppressed. In addition, a luminous flux toward directly above the light source 11 travels while spreading inside the transparent resin layer 18 and is refracted and further diffused when emitted to the lower surface of the light guide plate 10. The first direction changing portion 30 or the second direction changing portion 40 may be provided in the transparent resin layer 18.

### Eighth Embodiment

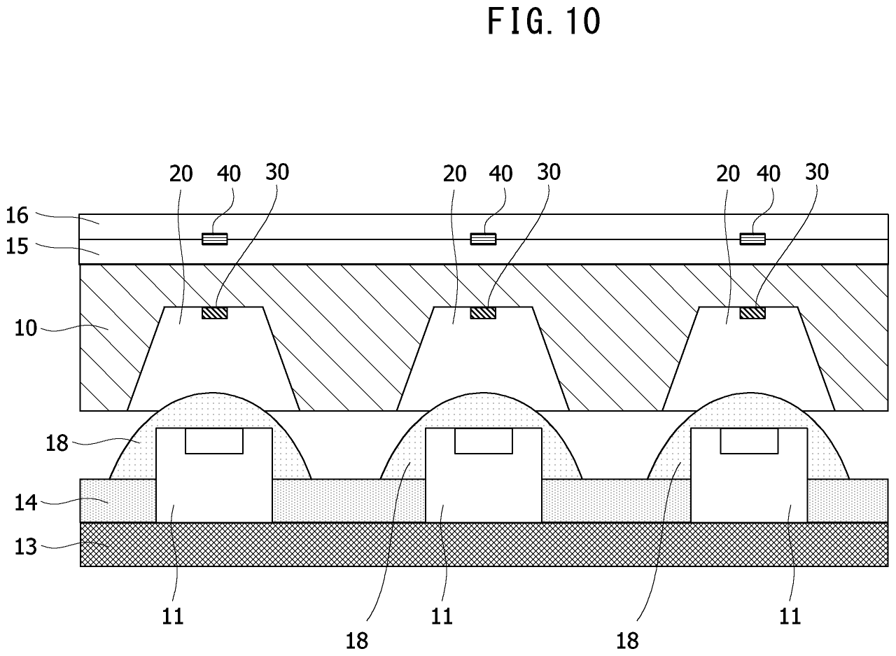

FIG. 10 is a sectional view schematically showing the light guide plate 10 according to an eighth embodiment. A ratio of sizes of the respective components and the like are not limited to the illustrated example. In the present embodiment, components corresponding to the configurations described above will be assigned corresponding reference numerals and a description thereof will be omitted.

In an example shown in FIG. 10, the light sources 11 are similarly embedded in the transparent resin layer 18. Even in such a configuration, the transparent resin layer 18 can be described as being arranged between the light guide plate 10 and the plurality of light sources 11 and the reflective layer 14. The transparent resin layer 18 is arranged below the light guide plate 10 and the light sources 11 are not housed inside the depressed portions 20 of the light guide plate 10. In addition, the lower surface of the light guide plate 10 and the reflective layer 14 are not in contact with each other. Furthermore, the lower surface of the light guide plate 10 and the transparent resin layer 18 may or may not be in contact with each other. While the transparent resin layer 18 shown in FIG. 10 has an approximately hemispherical shape, the transparent resin layer 18 is not limited to this shape and may have a projection shape (convex shape) such as a columnar shape, a prismatic shape, a conical shape, or a pyramid shape. In addition, a part of the transparent resin layer 18 may be positioned inside the depressed portions 20 of the light guide plate 10 or the transparent resin layer 18 may not be positioned inside the depressed portions 20 of the light guide plate 10. Furthermore, the transparent resin layer 18 may be in contact with an interior of the depressed portions 20. Light emitted from the light sources 11 passes through the transparent resin layer 18 and is made incident into the light guide plate 10.

Even in the present embodiment, the first direction changing portion 30 and the second direction changing portion 40 are provided at positions similar to those in the second embodiment and the like. Even according to such a configuration, straight light emitted directly upward from the light source 11 can be shielded, reflected, or diffused and an occurrence of brightness non-uniformity can be suppressed. In addition, a luminous flux toward directly above the light source 11 travels while spreading inside the transparent resin layer 18 and is refracted and further diffused when emitted from the transparent resin layer 18. The first direction changing portion 30 or the second direction changing portion 40 may be provided in the transparent resin layer 18.

### Ninth Embodiment

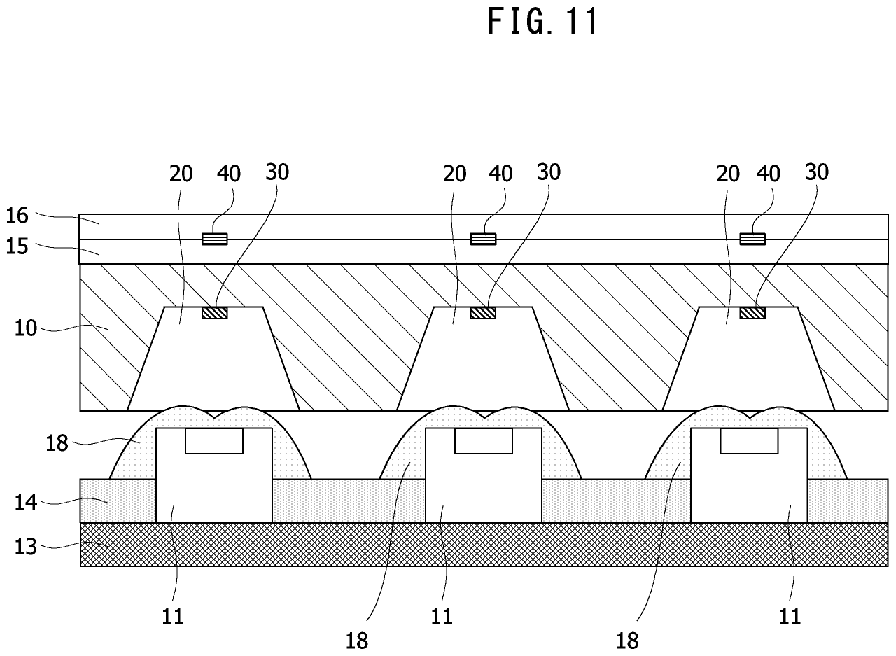

FIG. 11 is a sectional view schematically showing the light guide plate 10 according to a ninth embodiment. A ratio of sizes of the respective components and the like are not limited to the illustrated example. In the present embodiment, components corresponding to the configurations described above will be assigned corresponding reference numerals and a description thereof will be omitted.

In an example shown in FIG. 11, the light sources 11 are similarly embedded in the transparent resin layer 18. For example, the transparent resin layer 18 has a donut shape which is an approximately hemispherical upward-convex shape and which is depressed near a center in a plan view but a periphery of the depression protrudes upward in an annular belt shape. Alternatively, the transparent resin layer 18 may have a shape in which two approximately hemispherical shapes are connected to each other. The transparent resin layer 18 is arranged below the light guide plate 10 and the light sources 11 are not housed inside the depressed portions 20 of the light guide plate 10. The lower surface of the light guide plate 10 and the reflective layer 14 are not in contact with each other. Furthermore, the lower surface of the light guide plate 10 and the transparent resin layer 18 may or may not be in contact with each other. In addition, a part of the transparent resin layer 18 may be positioned inside the depressed portions 20 of the light guide plate 10 or the transparent resin layer 18 may not be positioned inside the depressed portions 20 of the light guide plate 10. Furthermore, the transparent resin layer 18 may be in contact with an interior of the depressed portions 20. Light emitted from the light sources 11 passes through the transparent resin layer 18 and is made incident into the light guide plate 10.

Even in the present embodiment, the first direction changing portion 30 and the second direction changing portion 40 are provided at positions similar to those in the second embodiment and the like. Even according to such a configuration, straight light emitted directly upward from the light source 11 can be shielded, reflected, or diffused and an occurrence of brightness non-uniformity can be suppressed. In addition, a luminous flux toward directly above the light source 11 travels while spreading inside the transparent resin layer 18 and is refracted and further diffused when emitted from the transparent resin layer 18. The first direction changing portion 30 or the second direction changing portion 40 may be provided in the transparent resin layer 18.

### Tenth Embodiment

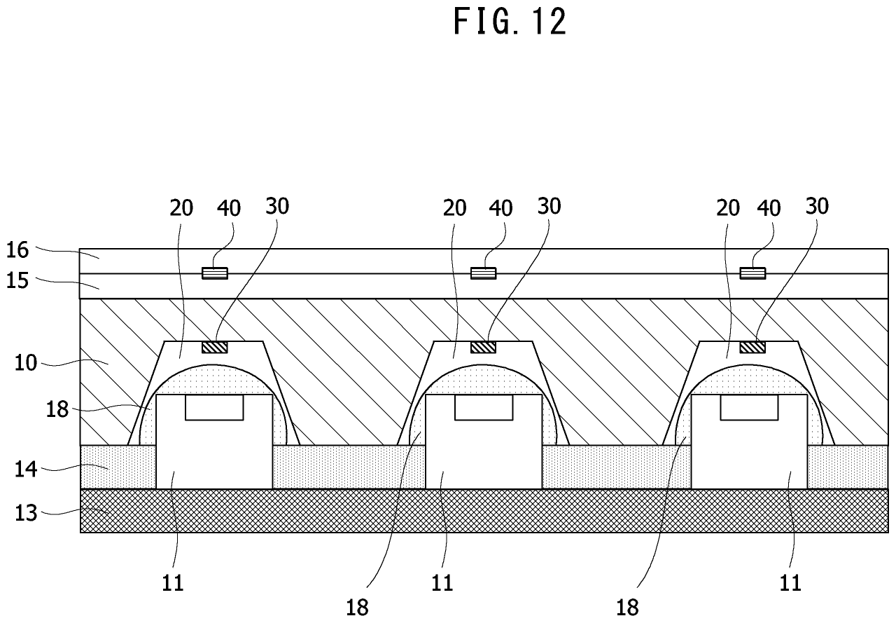

FIG. 12 is a sectional view schematically showing the light guide plate 10 according to a tenth embodiment. A ratio of sizes of the respective components and the like are not limited to the illustrated example. In the present embodiment, components corresponding to the configurations described above will be assigned corresponding reference numerals and a description thereof will be omitted.

In an example shown in FIG. 12, the light sources 11 are similarly embedded in the transparent resin layer 18. Even in such a configuration, the transparent resin layer 18 can be described as being arranged between the light guide plate 10 and the plurality of light sources 11 and the reflective layer 14. The transparent resin layer 18 is provided below the light guide plate 10 and is housed inside the depressed portions 20. Furthermore, the lower surface of the light guide plate 10 and the transparent resin layer 18 may or may not be in contact with each other. While the transparent resin layer 18 shown in FIG. 10 has an approximately hemispherical shape, the transparent resin layer 18 is not limited to this shape and may have a projection shape (convex shape) such as a columnar shape, a prismatic shape, a conical shape, or a pyramid shape. Furthermore, the transparent resin layer 18 may be in contact with an interior of the depressed portions 20. Light emitted from the light sources 11 passes through the transparent resin layer 18 and is made incident into the light guide plate 10.

Even in the present embodiment, the first direction changing portion 30 and the second direction changing portion 40 are provided at positions similar to those in the second embodiment and the like. Even according to such a configuration, straight light emitted directly upward from the light source 11 can be shielded, reflected, or diffused and an occurrence of brightness non-uniformity can be suppressed. In addition, a luminous flux toward directly above the light source 11 travels while spreading inside the transparent resin layer 18 and is refracted and further diffused when emitted from the transparent resin layer 18. The first direction changing portion 30 or the second direction changing portion 40 may be provided in the transparent resin layer 18.

### Eleventh Embodiment

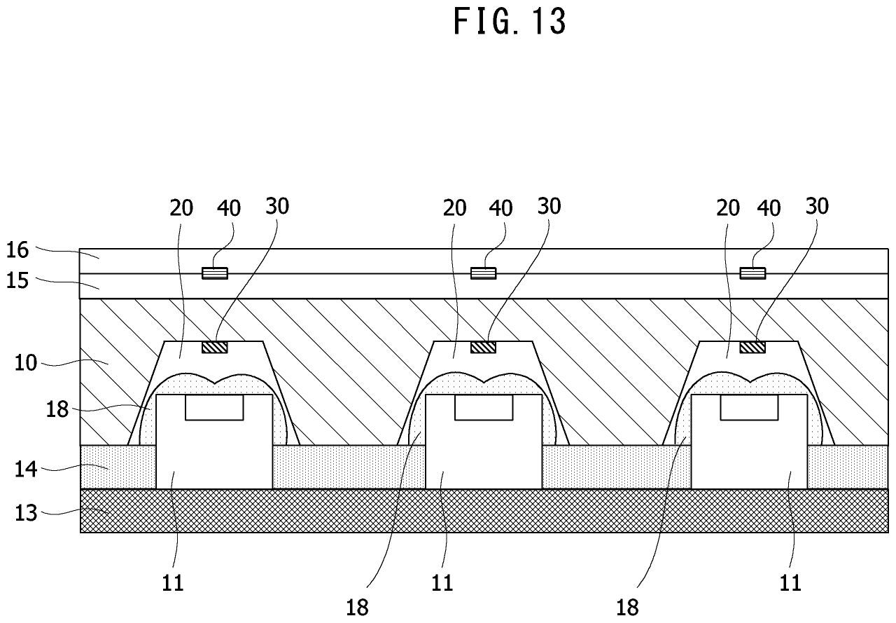

FIG. 13 is a sectional view schematically showing the light guide plate 10 according to an eleventh embodiment. A ratio of sizes of the respective components and the like are not limited to the illustrated example. In the present embodiment, components corresponding to the configurations described above will be assigned corresponding reference numerals and a description thereof will be omitted.

In an example shown in FIG. 13, the light sources 11 are similarly embedded in the transparent resin layer 18. Even in such a configuration, the transparent resin layer 18 can be described as being arranged between the light guide plate 10 and the plurality of light sources 11 and the reflective layer 14. For example, the transparent resin layer 18 has a donut shape which is an approximately hemispherical upward-convex shape and which is depressed near a center in a plan view but a periphery of the depression protrudes upward in an annular belt shape. Alternatively, the transparent resin layer 18 may have a shape in which two approximately hemispherical shapes are connected to each other. The transparent resin layer 18 is arranged below the light guide plate 10 and the light sources 11 are housed inside the depressed portions 20 of the light guide plate 10. In addition, the lower surface of the light guide plate 10 and the reflective layer 14 are in contact with each other. Furthermore, the lower surface of the light guide plate 10 and the transparent resin layer 18 may or may not be in contact with each other. Moreover, the transparent resin layer 18 may be in contact with an interior of the depressed portions 20. Light emitted from the light sources 11 passes through the transparent resin layer 18 and is made incident into the light guide plate 10.

Even in the present embodiment, the first direction changing portion 30 and the second direction changing portion 40 are provided at positions similar to those in the second embodiment and the like. Even according to such a configuration, straight light emitted directly upward from the light source 11 can be shielded, reflected, or diffused and an occurrence of brightness non-uniformity can be suppressed. In addition, a luminous flux toward directly above the light source 11 travels while spreading inside the transparent resin layer 18 and is refracted and further diffused when emitted from the transparent resin layer 18. The first direction changing portion 30 or the second direction changing portion 40 may be provided in the transparent resin layer 18.

### Twelfth Embodiment

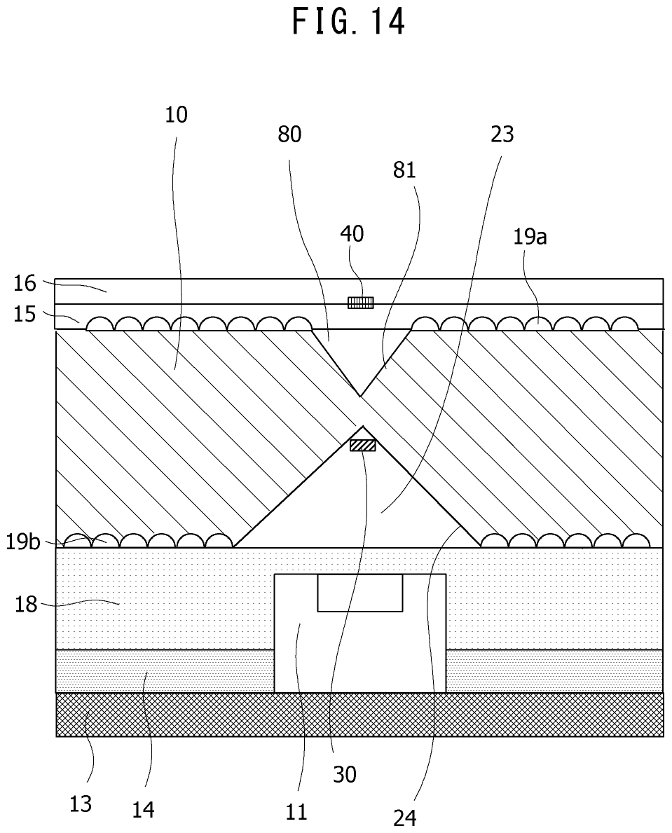

FIG. 14 is a sectional view schematically showing the light guide plate 10 according to a twelfth embodiment. A ratio of sizes of the respective components and the like are not limited to the illustrated example. In the present embodiment, components corresponding to the configurations described above will be assigned corresponding reference numerals and a description thereof will be omitted.

In FIG. 14, the transparent resin layer 18 is arranged between the light guide plate 10 and the plurality of light sources 11 and the reflective layer 14. In other words, the plurality of light sources 11 are embedded in the transparent resin layer 18. Even in such a configuration, the transparent resin layer 18 can be described as being arranged between the light guide plate 10 and the plurality of light sources 11 and the reflective layer 14. In addition, the light guide plate 10 is arranged on top of the transparent resin layer 18 and the light sources 11 are not housed inside the depressed portions 20 of the light guide plate 10. Furthermore, the light guide plate 10 is provided with the depressed portion 23 and the depressed portion 80 in a similar manner to the fifth embodiment and the like. The depressed portion 23 and the depressed portion 80 have a conical shape, a pyramid shape, a bowl shape, a bell shape, or the like. In addition, the first direction changing portion 30 is provided in a back portion inside the depressed portion 23. Furthermore, the second direction changing portion 40 is provided between the diffusing sheet 15 and the prism sheet 16 near directly above the light source 11.

The light guide plate 10 according to the present embodiment has the depressed portion 23 and the depressed portion 80 in a similar manner to the fifth embodiment. In addition, the light guide plate 10 according to the present embodiment has convex dot patterns 19a on a side of the light exit surface and concave dot patterns 19b on a lower surface side. The dot patterns 19a are provided around the depressed portion 80 in a plan view. In a similar manner, the dot patterns 19b are provided around the depressed portion 23 in a plan view. The dot patterns 19a and 19b may be respectively provided on the entire light exit surface and the entire lower surface of the light guide plate 10. The dot patterns 19a have a projection shape such as a convex lens shape, a columnar shape, a prismatic shape, a conical shape, or a pyramid shape. In addition, the dot patterns 19b have a concave shape such as a concave lens shape, a columnar groove shape, a prismatic groove shape, a conical groove shape, or a pyramid groove shape. The dot patterns 19a and 19b may be any of a circle, an ellipse, and a polygon in a plan view. In addition, the dot patterns 19a and 19b may be integrally formed with the light guide plate 10 when the light guide plate 10 is manufactured by injection molding. Alternatively, the dot patterns 19a and 19b may be separately formed on the light guide plate 10 by an ink-jet or the like. Due to the dot patterns 19a and 19b, light can be diffused on the lower surface or the light exit surface of the light guide plate 10. In addition, an interior of the depressed portion 23 or the depressed portion 80 may have minute irregularities. Accordingly, light incident to the depressed portion 23 or the depressed portion 80 can be further diffused.

In the present embodiment, the first direction changing portion 30 and the second direction changing portion 40 are provided at positions similar to those in the second embodiment. Even according to such a configuration, straight light emitted directly upward from the light source 11 can be shielded, reflected, or diffused and an occurrence of brightness non-uniformity can be suppressed. In addition, a luminous flux toward directly above the light source 11 travels while spreading inside the transparent resin layer 18 and is refracted and further diffused when emitted from the transparent resin layer 18. The first direction changing portion 30 or the second direction changing portion 40 may be provided in the transparent resin layer 18.

A display apparatus including the light guide plate 10 described in the first to sixth embodiments can be mounted to various electronic devices. Examples of electronic devices provided with such a display apparatus include a smartphone, a digital camera, a tablet terminal, an electronic book, a wearable device, a car navigation apparatus, an electronic dictionary, and an electronic billboard. Using the light guide plate and the display apparatus according to the embodiment enables brightness non-uniformity of electronic devices to be reduced while reducing sizes and thicknesses of the electronic devices.

### REFERENCE SIGNS LIST

1 Planar light source apparatus
10 Light guide plate
11 Light source
12 Frame
13 Mounting substrate
14 Reflective layer
15 Diffusing sheet
16 Prism sheet
17 Light shielding member
20, 22, 23, 25 Depressed portion
21, 24 Side surface
26 Irregularities
30 First direction changing portion
40 Second direction changing portion
50 Light diffusing layer
51 Protruded portion
60 First diffraction grating
70 Second diffraction grating
80, 90 Depressed portion
81 Side surface
91 Irregularities
2 Display panel

1-10. (canceled)

11. A planar light source apparatus, comprising:
a substrate:
a light source provided on the substrate;
a light guide member having a light exit surface from which light is emitted, an opposite surface, which is on an opposite side of the light exit surface, and a through-hole, comprising an opening on the opposite surface and an opening on the light exit surface, inside which the light source can be located;
a reflective layer arranged between the substrate and the light guide member:
a transparent resin layer arranged between the reflective layer and the light guide member:
and
a light diffusing member configured to diffuse at least a part of light of the light source,
wherein the light diffusing member comprises:
a first diffusing portion which is provided inside the through-hole and above the light source and which diffuses at least a part of light of the light source; and
a second diffusing portion from which the first diffusing portion is formed and from which the first diffusion portion protrudes, and which is provided above the light source and on a side farther from the light source than the light exit surface and which diffuses at least a part of light of the light source, wherein
the first diffusing portion is inserted into the through-hole,
wherein one surface of the transparent resin layer is in contact with the reflective layer, and the other surface of the transparent resin layer is in contact with the opposite surface of the light guide member,
wherein the transparent resin layer is contact with the light source.

12. The planar light source apparatus according to claim 11, wherein
the first diffusing portion and the second diffusing portion are each formed from a material that diffuses light.

13. The planar light source apparatus according to claim 11, wherein
the first diffusing portion and the second diffusing portion are each made of resin material having particles with random sizes and different refractive indexes dispersed therein.

14. The planar light source apparatus according to claim 11, wherein
the reflective layer is a resin layer, and extends into the through-hole so as to cover a surface of the substrate at the opening on the opposite surface of the light guide member.

15. A display apparatus, comprising:
the planar light source apparatus according to claim 11; and
a display panel which receives light emitted from the planar light source apparatus.

16. An electronic device comprising the display apparatus according to claim 15.
